(19) United States
(12) Patent Application Publication
(10) Pub. No.: US 2025/0393276 A1
(43) Pub. Date: Dec. 25, 2025

(54) SEMICONDUCTOR DEVICE WITH ISOLATION STRUCTURE AND METHOD FOR MANUFACTURING THE SAME

(71) Applicant: Taiwan Semiconductor Manufacturing Company, Ltd., Hsinchu (TW)

(72) Inventors: Fu-Hsiang SU, Hsinchu (TW); Wen-Li CHIU, Hsinchu (TW); Hong-Chih CHEN, Hsinchu (TW); Chia-Hao KUO, Hsinchu (TW); Shih-Hsun CHANG, Hsinchu (TW)

(73) Assignee: Taiwan Semiconductor Manufacturing Company, Ltd., Hsinchu (TW)

(21) Appl. No.: 18/753,470

(22) Filed: Jun. 25, 2024

(51) Int. Cl. H01L 29/66; H01L 21/762; H01L 29/06; H01L 29/423; H01L 29/51

(52) U.S. Cl. CPC H10D 64/017; H01L 21/76224; H10D 64/691; H10D 30/6735; H10D 62/121

(57) ABSTRACT

A method for manufacturing a semiconductor device includes: forming a dummy poly gate on a common edge of a first oxide-definition region and a second oxide-definition region, the dummy poly gate covering a stack unit, and including two first portions and a second portion disposed between the two first portions in a first direction, the first portion having a width in a second direction transverse to the first direction, the second portion having a width in the second direction, the width of the second portion being larger than the width of the first portion; forming first and second source/drain features on the first and second oxide-definition regions, respectively; removing the second portion to form a first opening that exposes the stack unit; removing the stack unit to form a second opening in spatial communication with the first opening; and forming an isolation structure in the first and second openings.

### BACKGROUND

A continual reduction in minimum feature size of an integrated circuit (IC) chip is a trend in the semiconductor industry. Since the features of an IC chip (including semiconductor devices) are being scaled down, device packing density and device performance are affected by the changes in device layout and isolation structures. In order to avoid leakage between neighboring semiconductor devices (e.g., transistors), in a standard cell layout, edges of oxide-definition (OD) regions (such as active regions of the standard cell) are formed with isolation structures (such as, connected polysilicon-on-OD-edge (CPODE) structures).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2 to 17C are schematic views illustrating some intermediate stages of the method as depicted in FIGS. 1A and 1B in accordance with some embodiments.

FIGS. 18A and 18B are schematic views illustrating a semiconductor device in accordance with some embodiments.

FIGS. 19A and 19B are schematic views illustrating a semiconductor device in accordance with some embodiments.

FIGS. 20A and 20B are schematic views illustrating a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain region(s)” or the term “source/drain feature(s)” may refer to a source or a drain, individually or collectively dependent upon the context.

Semiconductor devices (e.g., complementary metal-oxide-semiconductor (CMOS) transistors) included in an integrated circuit (IC) chip have wide applications, such as an image sensor, a memory chip, etc. A structure of a CMOS transistor (such as a get-all-around (GAA) transistor) generally includes two source/drain regions, an active region (including a plurality of silicon channels) disposed between the two source/drain regions, a metal gate disposed on the active region, two contact plugs (i.e., metal on diffusion (MD)) respectively disposed on the two source/drain regions, and isolation structures. In a process for manufacturing IC chips, a plurality of isolation structures (e.g., a plurality of connected polysilicon-on-oxide-definition (OD) edge (CPODE) structures) are formed in each of the IC chips. Certain issues may occur with the scaling down of the feature sizes of the IC chips, which may adversely affect production yield of the IC chips. For example, if polysilicon is not fully removed in an etching process for forming a trench that is subsequently filled with a dielectric layer for formation of the CPODE structures, polysilicon residues will be formed near the CPODE structures. Therefore, these issues need to be solved in order to increase the production yield of the IC chips.

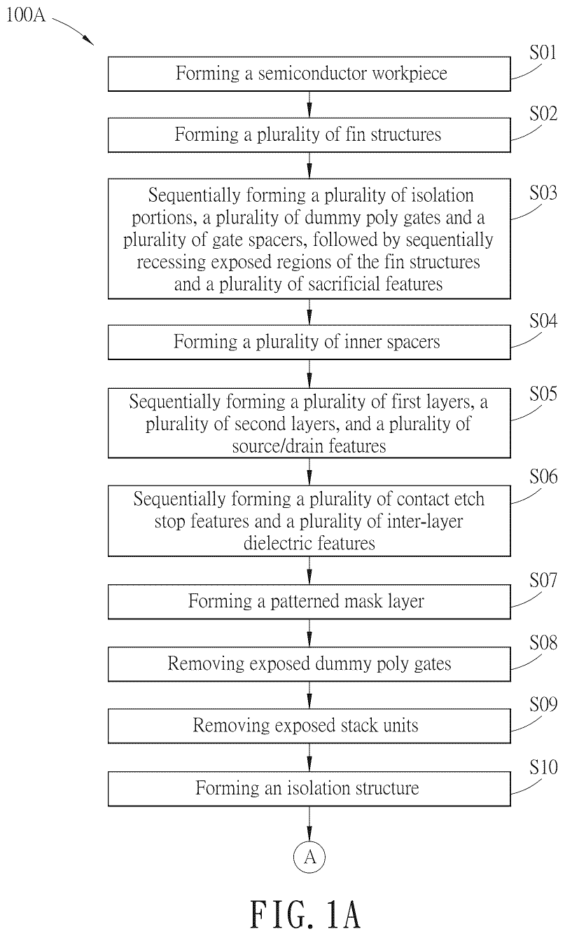

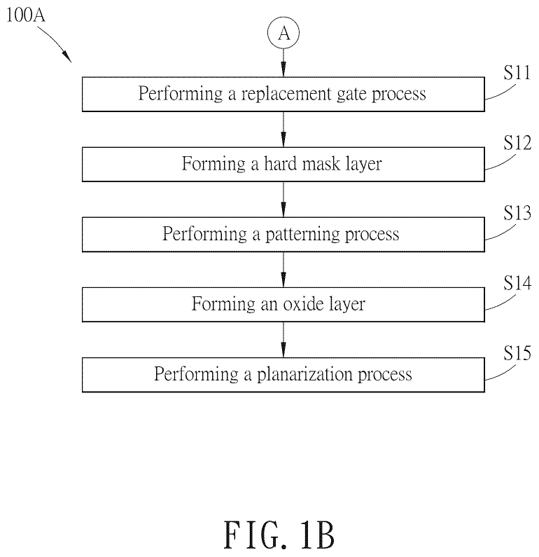

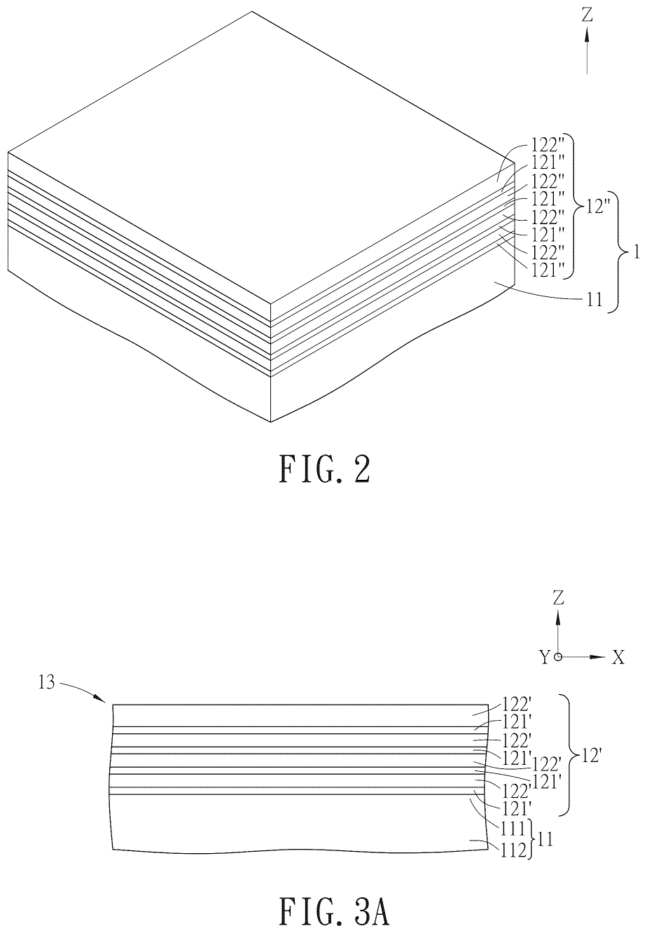

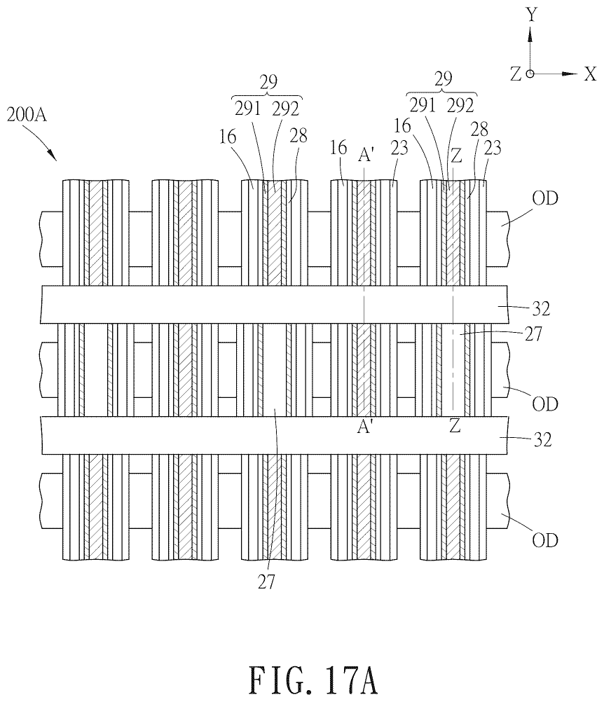

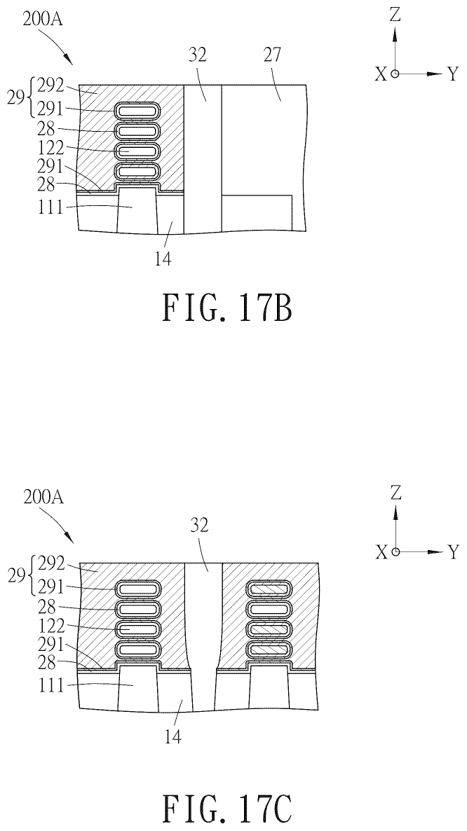

The present disclosure is directed to a semiconductor device and a method for manufacturing the same. FIGS. 1A and 1B are flow diagrams illustrating a method 100A for manufacturing a semiconductor device 200A shown in FIGS. 17A to 17C in accordance with some embodiments. FIGS. 2 to 16C illustrate schematic views of some intermediate stages of the method 100A. Some portions may be omitted in FIGS. 2 to 16C for the sake of brevity. Additional steps can be provided before, after or during the method 100A, and some of the steps described herein may be replaced by other steps or be eliminated.

Referring to FIG. 1A and the example illustrated in FIG. 2, the method 100A begins at step S01, where a semiconductor workpiece 1 is formed. Step S01 may be performed by forming a nanosheet stack 12″ over a semiconductor substrate 11 in a Z direction, which is perpendicular to a bottom surface of the semiconductor substrate 11. In some embodiments, the semiconductor substrate 11 may include, for example, but not limited to, an elemental semiconductor or a compound semiconductor. The elemental semiconductor includes a single species of atoms, such as silicon (Si) or germanium (Ge) from column XIV of the periodic table, and may be crystalline, polycrystalline, or amorphous in structure. Other suitable materials for the elemental semiconductor are within the contemplated scope of the present disclosure. The compound semiconductor includes two or more elements, and examples thereof may include, for example, but not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable materials for the compound semiconductor are within the contemplated scope of the present disclosure. The compound semiconductor may have a gradient feature in which the compositional ratio thereof changes from one location to another location in the compound semiconductor. The compound semiconductor may be formed over a silicon substrate and may be strained. In some embodiments, the semiconductor substrate 11 may include a multilayer compound semiconductor structure. In some embodiments, the nanosheet stack 12″ includes a plurality of sacrificial layers 121″ and a plurality of channel layers 122″ which are alternately stacked on the semiconductor substrate 11 in the Z direction. In some embodiments, the sacrificial layers 121″ may include silicon germanium (SiGe). Other suitable materials (for example, but not limited to, silicon oxide) for the sacrificial layers 121″ are within the contemplated scope of the present disclosure. In some embodiments, the channel layers 122″ may include silicon (Si). Other suitable materials for the channel layers 122″ are within the contemplated scope of the present disclosure. The sacrificial layers 121″ and the channel layers 122″ may be formed by a suitable deposition process, for example, but not limited to, chemical vapor deposition (CVD) (e.g., ultra-high vacuum CVD (UHV-CVD)) or other suitable deposition processes. In some embodiments, the sacrificial layers 121″ and the channel layers 122″ may be formed by a suitable epitaxial process, for example, but not limited to, molecular beam epitaxy (MBE) or other suitable epitaxial processes.

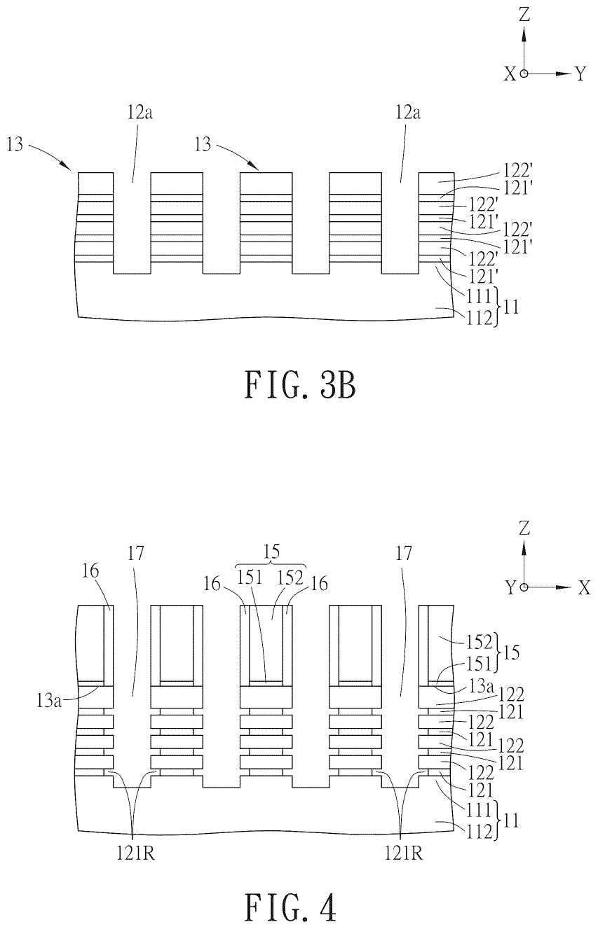

Referring to FIG. 1A and the example illustrated in FIGS. 3A and 3B, the method 100A then proceeds to step S02, where the structure shown in FIG. 2 is patterned to form a plurality of fin structures 13 that are spaced apart from each other by trenches 12a in a Y direction transverse to the Z direction (see FIG. 3B). Step S02 may be performed by a photolithography process, which includes an etching process. The etching process may be performed using, for example, but not limited to, an anisotropic etching process (for example, dry etching or other suitable anisotropic etching processes). Each of the trenches 12a may penetrate the nanosheet stack 12″ (see FIG. 2) and an upper portion 111 of the semiconductor substrate 11, and terminate at a lower portion 112 of the semiconductor substrate 11. In some embodiments, an upper surface of each of the fin structures 13 may have a plurality of covering regions 13a (see FIG. 4) and a plurality of exposed regions (not shown) that are separated from one another in an X direction transverse to the Y and Z directions. After this step, each of the sacrificial layers 121″ is formed into a plurality of sacrificial layer portions 121′, and each of the channel layers 122″ is formed into a plurality of channel layer portions 122′.

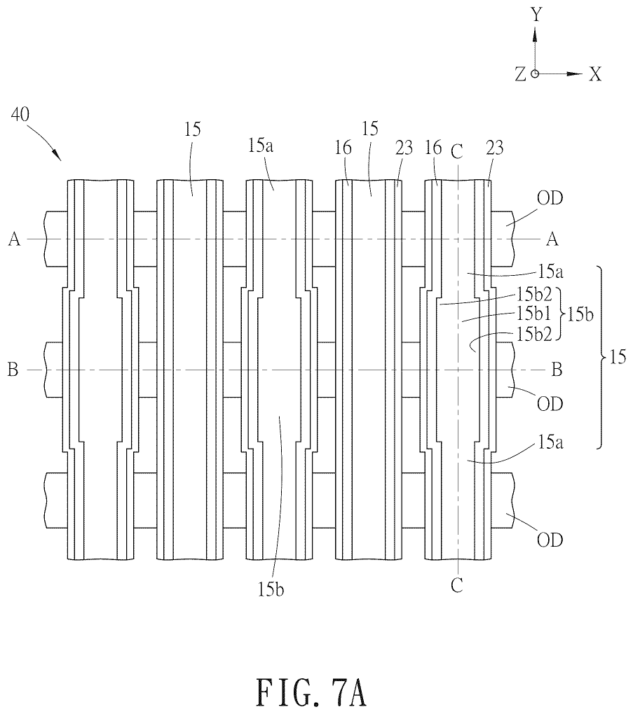

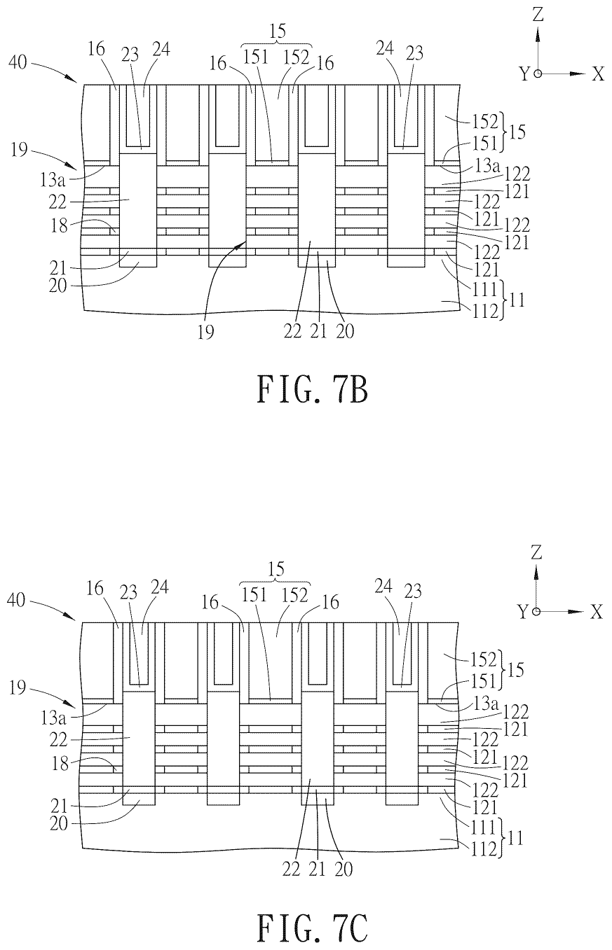

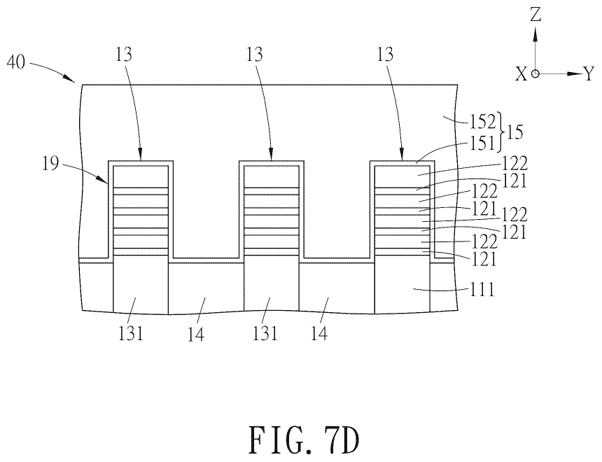

Referring to FIG. 1A and the example illustrated in FIG. 4, the method 100A then proceeds to step S03, where a plurality of isolation portions 14 (see FIG. 7D), a plurality of dummy poly gates 15, and a plurality of gate spacers 16 are sequentially formed, followed by sequentially recessing the exposed regions of the fin structures 13 and a plurality of sacrificial features 121. Step S03 may include sub-steps (i) to (v).

In sub-step (i), the isolation portions 14 shown in FIG. 7D are formed on the semiconductor substrate 11. Two adjacent ones of the isolation portions 14 are located at two opposite sides of a lower fin portion 131 (see FIG. 7D) of a corresponding one of the fin structures 13, so as to separate and isolate the fin structures 13 from each other. The two opposite sides of the lower fin portion 131 are opposite to each other in the Y direction. In some embodiments, the isolation portions 14 may be made of an oxide-based material (e.g., silicon oxide), a nitride-based material (e.g., silicon nitride), or a combination thereof. Other suitable materials for the isolation portions 14 are within the contemplated scope of the present disclosure. In some embodiments, the isolation portions 14 may be formed by a suitable deposition process, for example, but not limited to, CVD, physical vapor deposition (PVD), or other suitable deposition processes. In some embodiments, each of the isolation portions 14 may be a portion of a shallow trench isolation (STI), a deep trench isolation (DTI), or other suitable isolation structures.

In sub-step (ii), the dummy poly gates 15 are formed on the isolation portions 14 and over the fin structures 13, and are spaced apart from each other in the X direction. In some embodiments, each of the dummy poly gates 15 may include a dummy gate dielectric 151, a dummy gate electrode 152, a polish stop layer (not shown), and a hard mask layer (not shown).

The dummy gate dielectric 151 of each of the dummy poly gates 15 is disposed on a corresponding one of the covering regions 13a. The dummy gate dielectric 151 may be made of an oxide-based material (e.g., silicon oxide). Other suitable materials for the dummy gate dielectric 151 are within the contemplated scope of the present disclosure.

The dummy gate electrode 152 is disposed on the dummy gate dielectric 151. The dummy gate electrode 152 may include polysilicon. Other suitable materials for the dummy gate electrode 152 are within the contemplated scope of the present disclosure.

The polish stop layer is disposed on the dummy gate electrode 152 opposite to the dummy gate dielectric 151. The polish stop layer may include silicon nitride, silicon oxide, silicon oxynitride, or combinations thereof. Other suitable materials for the polish stop layer are within the contemplated scope of the present disclosure.

The hard mask layer is disposed on the polish stop layer opposite to the dummy gate electrode 152. The hard mask layer may include silicon nitride, silicon oxide, silicon oxynitride, or combinations thereof. Other suitable materials for the hard mask layer are within the contemplated scope of the present disclosure.

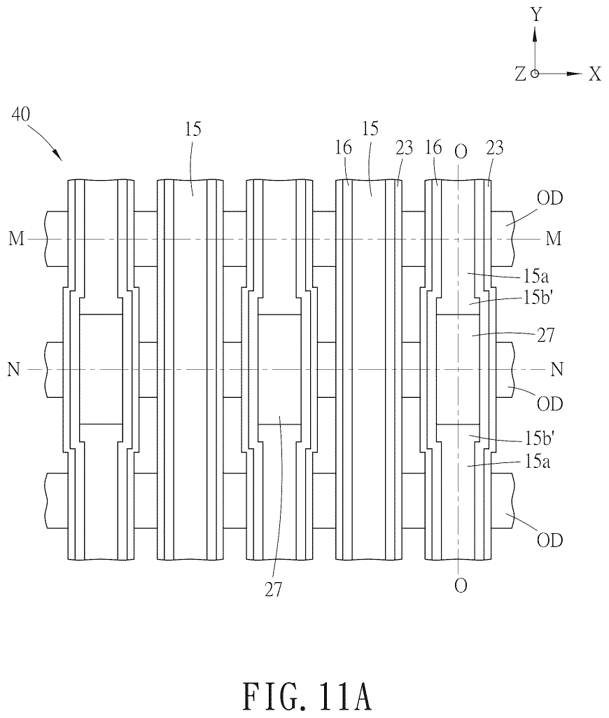

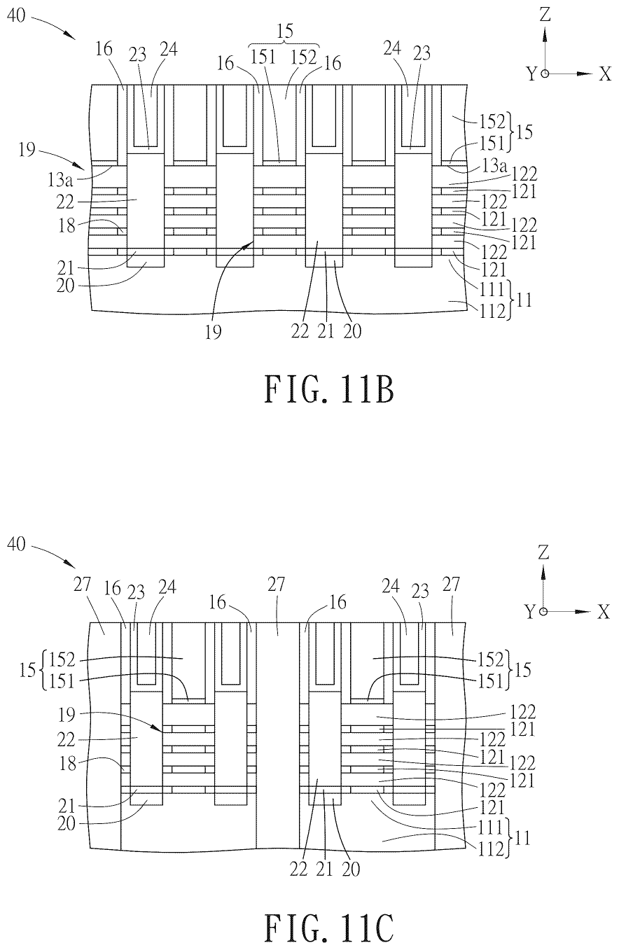

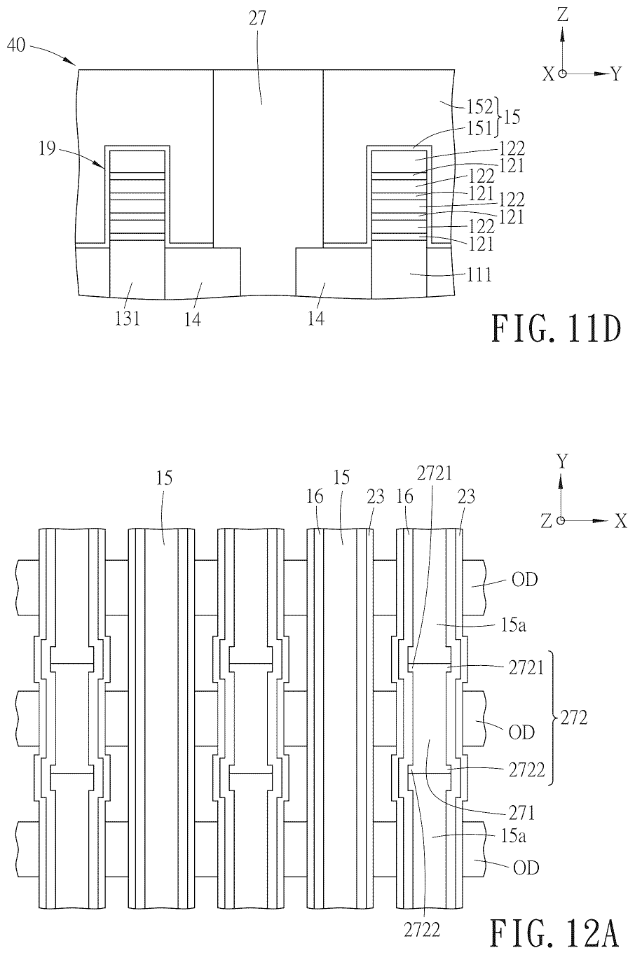

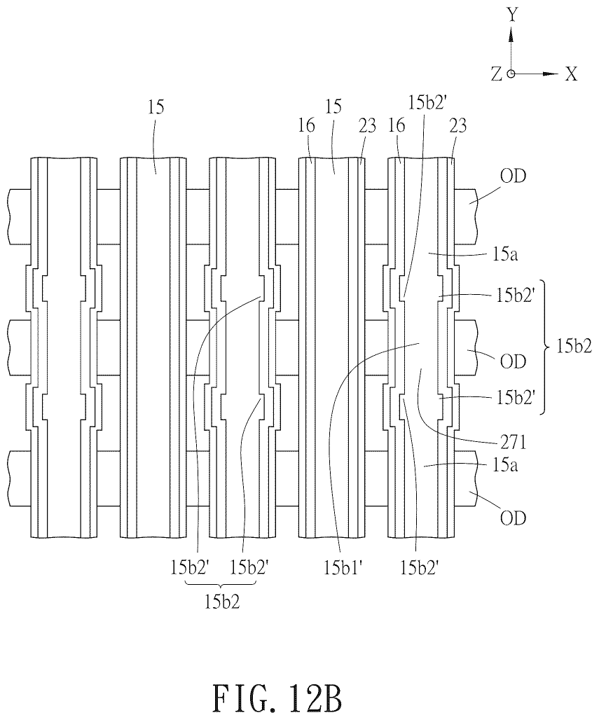

In some embodiments, each of the dummy poly gates 15 to be formed with an isolation structure 27 (see FIGS. 11A to 11D) may be divided into a plurality of first portions 15a and a plurality of second portions 15b (see FIG. 7A). In some embodiments, each of the second portions 15b is disposed between two adjacent ones of the first portions 15a along the Y direction. In some embodiments, each of the second portions 15b has a width in the X direction, each of the first portions 15a has a width in the X direction, and the width of each of the second portions 15b is larger than the width of each of the first portions 15a. In some embodiments, each of the second portions 15b may be divided into a main part 15b1 and two jog parts 15b2 that respectively protrude from two opposite sides of the main part 15b1 in the X direction (see FIG. 12B). In some embodiments, each of the two jog parts 15b2 extends in the Y direction. In some embodiments, a width of the main part 15b1 of the second portion 15b may be the same as the width of the first portion 15a.

In sub-step (iii), each pair of the gate spacers 16 are respectively formed at two opposite sides of a corresponding one of the dummy poly gates 15 in the X direction. The gate spacers 16 may include, for example, but not limited to, silicon oxide, silicon nitride, silicon oxynitride, silicon carbon nitride, silicon oxycarbonnitride, or low-dielectric constant (k) materials. Other suitable materials for the gate spacers 16 are within the contemplated scope of the present disclosure. In some embodiments, each of the gate spacers 16 may be formed as a single layer structure or a multi-layered structure.

In sub-step (iv), the exposed regions of the fin structures 13 are recessed by a suitable etching process, for example, but not limited to, dry etching, wet etching, other suitable etching processes, or combinations thereof, so as to form a plurality of source/drain trenches 17 that are spaced apart from each other in the X direction. After this sub-step, the sacrificial layer portions 121′ and the channel layer portions 122′ (see FIG. 3A or 3B) are respectively patterned into the sacrificial features 121 and channel features 122.

In sub-step (v), the sacrificial features 121 are laterally recessed by an isotropic etching process, for example, but not limited to, wet etching process or other suitable etching processes to remove side portions of the sacrificial features 121 based on a relatively high etching selectivity of the sacrificial features 121 with respect to the channel features 122, so as to form a plurality of lateral recesses 121R.

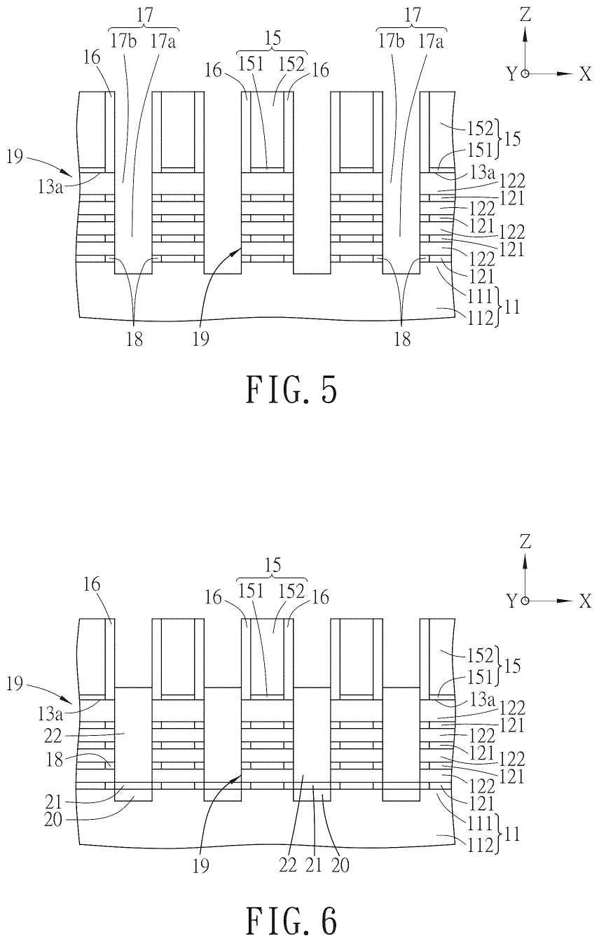

Referring to FIG. 1A and the example illustrated in FIG. 5, the method 100A then proceeds to step S04, where a plurality of inner spacers 18 are formed in the lateral recesses 121R (see FIG. 4). Step S04 may be performed by conformally depositing an spacer material layer (not shown) over the structure shown in FIG. 4 to fill the lateral recesses 121R, followed by isotropically etching the spacer material layer to form the inner spacers 18 in the lateral recesses 121R so as to laterally cover the sacrificial features 121. The spacer material layer may be formed by a suitable deposition process, for example, but not limited to, CVD, plasma-enhanced CVD (PECVD), PVD, atomic layer deposition (ALD), plasma-enhanced ALD (PEALD), or other suitable deposition processes. The spacer material layer for forming the inner spacers 18 may include, for example, but not limited to, silicon oxide, silicon nitride, silicon oxycarbide, silicon oxynitride, silicon carbon nitride, silicon oxycarbonitride, low-k materials, or combinations thereof. Other suitable materials for forming the inner spacers 18 are within the contemplated scope of the present disclosure. The isotropic etching process may be a dry isotropic etching process, a wet isotropic etching process, or a combination thereof. After this step, a plurality of stack units 19 are formed, and each of the stack units 19 includes the sacrificial features 121, the channel features 122, and the inner spacers 18, where each pair of the inner spacers 18 laterally covers a corresponding one of the sacrificial features 121.

Referring to FIG. 1A and the example illustrated in FIG. 6, the method 100A then proceeds to step S05, where a plurality of first layers 20, a plurality of second layers 21, and a plurality of source/drain features 22 are sequentially formed. Step S05 may include sub-steps (i) to (iii).

In sub-step (i), the first layers 20 are respectively formed in lower trench portions 17a of the source/drain trenches 17 (see FIG. 5). In some embodiments, the first layers 20 may be made of a semiconductor material, for example, but not limited to, silicon. Other suitable materials for forming the first layers 20 are within the contemplated scope of the present disclosure. In some embodiments, the first layers 20 may be formed by, for example, but not limited to, a deposition process (e.g., CVD), an epitaxial growth process (e.g., MBE), an epitaxial deposition/partial etch process (e.g., cyclic deposition-etch (CDE) process), or a selective epitaxial growth (SEG) process.

In sub-step (ii), the second layers 21 are respectively formed on the first layers 20 in the source/drain trenches 17. In some embodiments, the second layers 21 may be made of a dielectric material, for example, but not limited to, silicon oxide or silicon nitride. Other suitable materials for forming the second layers 21 are within the contemplated scope of the present disclosure. In some embodiments, the second layers 21 may be formed by a suitable deposition process, for example, but not limited to, CVD, ALD, or other suitable deposition processes.

In sub-step (iii), the source/drain features 22 are respectively formed on the second layers 21 in upper trench portions 17b of the source/drain trenches 17 (see FIG. 5). In some embodiments, the source/drain features 22 may be made of silicon phosphide, silicon germanium, or silicon germanium boron. Other suitable materials for forming the source/drain features 22 are within the contemplated scope of the present disclosure. In some embodiments, the source/drain features 22 may be formed by a suitable epitaxial growth process (e.g., MBE). In some embodiments, the first layers 20, the second layers 21, and the source/drain features 22 together serve as source/drain regions.

Referring to FIG. 1A and the example illustrated in FIGS. 7A to 7D, the method 100A then proceeds to step S06, where a plurality of contact etch stop features 23 and a plurality of inter-layer dielectric (ILD) features 24 are sequentially and respectively formed on the source/drain features 22. FIG. 7B illustrates a cross-sectional view taken along line A-A of FIG. 7A. FIG. 7C illustrates a cross-sectional view taken along line B-B of FIG. 7A. FIG. 7D illustrates a cross-sectional view taken along line C-C of FIG. 7A. In this step, a contact etch stop layer (not shown) for forming the contact etch stop features 23 and a dielectric material layer (not shown) for forming the ILD features 24 are sequentially formed over the structure shown in FIG. 6 by a blanket deposition process, for example, but not limited to, CVD or molecular layer deposition (MLD). In some embodiments, the contact etch stop layer for forming the contact etch stop features 23 may include, for example, but not limited to, silicon nitride, carbon-doped silicon nitride, other suitable contact etch stop materials, or combinations thereof. In some embodiments, the dielectric material layer for forming the ILD features 24 may include, for example, but not limited to, silicon oxide, silicon nitride, silicon oxynitride, other suitable dielectric materials, or combinations thereof. Other suitable materials for forming the contact etch stop features 23 and the ILD features 24 are within the contemplated scope of the present disclosure. After formation of the contact etch stop layer and the dielectric material layer, a planarization process, for example, but not limited to, chemical mechanical polishing (CMP) or other suitable planarization processes, is performed to remove an excess portion of the contact etch stop layer and an excess portion of the dielectric material layer, so as to obtain the contact etch stop features 23 and the ILD features 24. After this step, a semiconductor structure 40 is obtained. In some embodiments, the semiconductor structure 40 is a get-all-around (GAA) structure, and includes the stack units 19. In some embodiments, the stack units 19 (see FIG. 7B) are located among a plurality of oxide-definition (OD) regions (see FIG. 7A). In some embodiments, the second portion 15b of the dummy poly gate 15 has a rectangular shape.

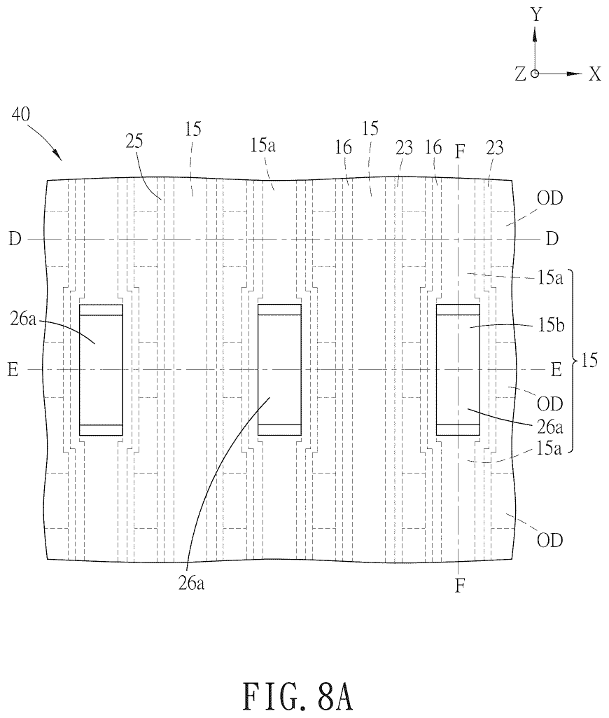

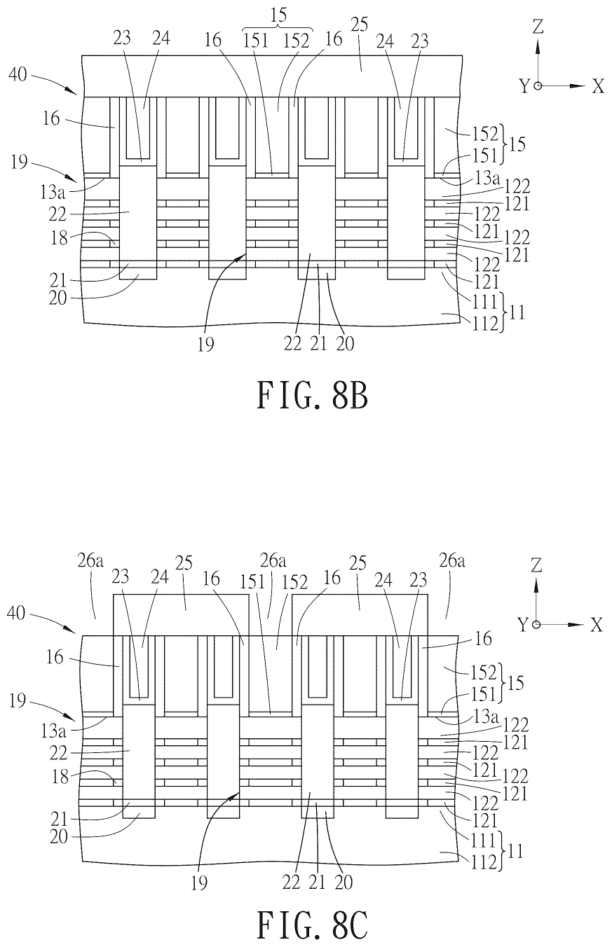

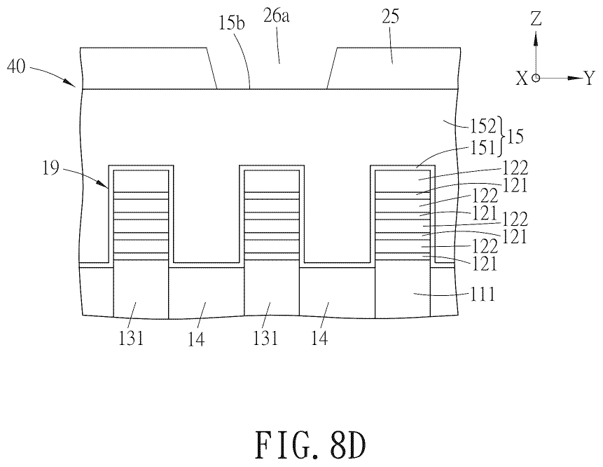

Referring to FIG. 1A and the example illustrated in FIGS. 8A to 8D, the method 100A then proceeds to step S07, where a patterned mask layer 25 is formed on the semiconductor structure 40 shown in FIGS. 7A to 7D. FIG. 8B illustrates a cross-sectional view taken along line D-D of FIG. 8A. FIG. 8C illustrates a cross-sectional view taken along line E-E of FIG. 8A. FIG. 8D illustrates a cross-sectional view taken along line F-F of FIG. 8A. In some embodiments, the patterned mask layer 25 may be made of a nitride-based material, for example, but not limited to, silicon nitride. Other suitable materials for forming the patterned mask layer 25 are within the contemplated scope of the present disclosure. In some embodiments, the patterned mask layer 25 is formed with a plurality of first openings 26a (see FIGS. 8C and 8D), and each of the first openings 26a exposes a corresponding one of the dummy poly gates 15 to be formed with the isolation structure 27 (see FIGS. 11A to 11D). In some embodiments, the second portion 15b of each of the dummy poly gates 15 to be formed with the isolation structure 27 is exposed from a corresponding one of the first openings 26a. In some embodiments, the patterned mask layer 25 is used as an etching mask to etch the second portion 15b of each of the dummy poly gates 15 to be formed with the isolation structure 27.

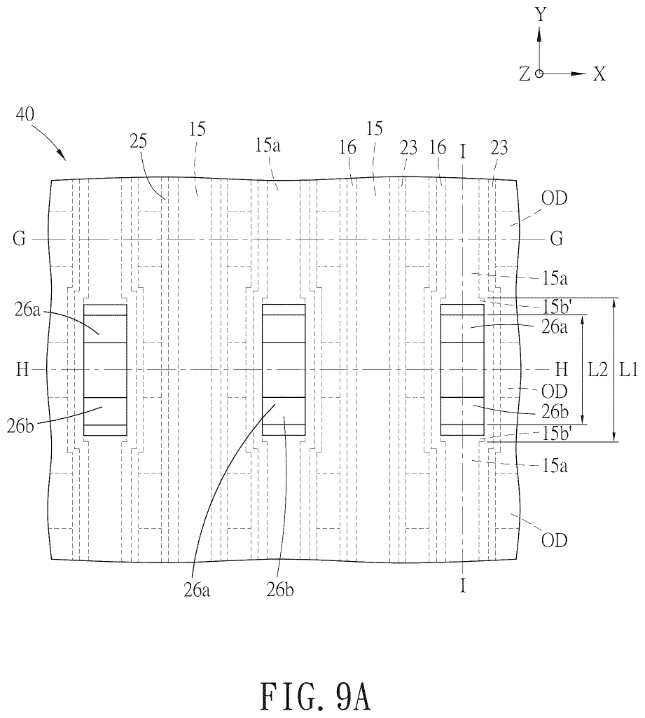

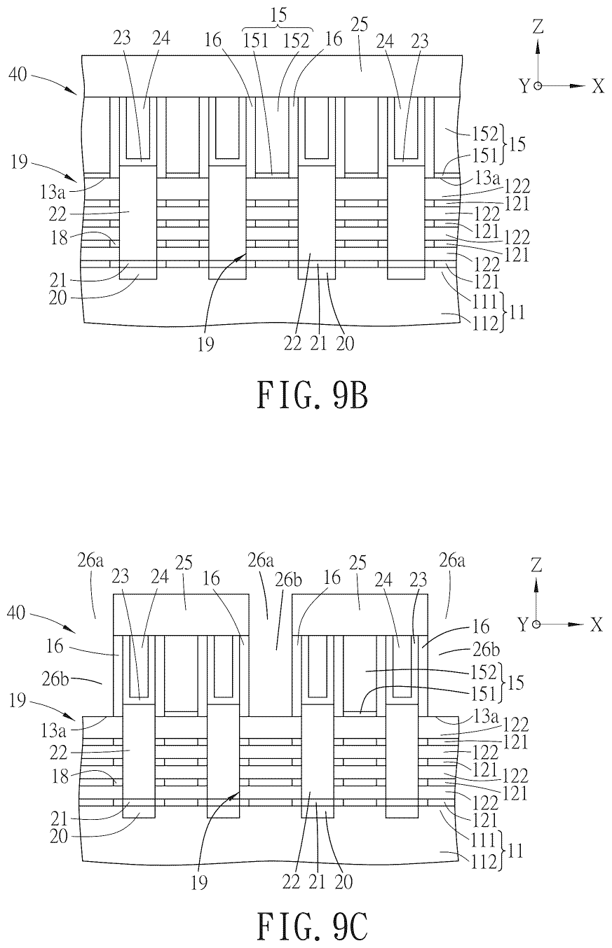

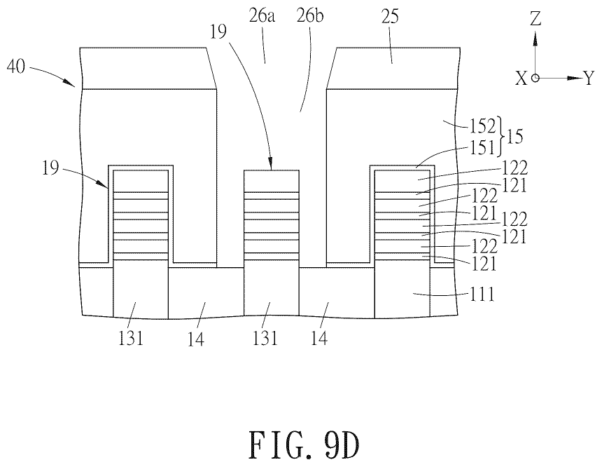

Referring to FIG. 1A and the example illustrated in FIGS. 9A to 9D, the method 100A then proceeds to step S08, where an etching process is performed to remove the second portion 15b of each of the dummy poly gates 15, which are to be formed with the isolation structure 27, through the corresponding one of the first openings 26a of the patterned mask layer 25 (see FIG. 8D). FIG. 9B illustrates a cross-sectional view taken along line G-G of FIG. 9A. FIG. 9C illustrates a cross-sectional view taken along line H-H of FIG. 9A. FIG. 9D illustrates a cross-sectional view taken along line I-I of FIG. 9A. Step S08 may be performed by a suitable etching process, for example, but not limited to, an anisotropic dry etching process or other suitable etching processes. After this step, a plurality of second openings 26b are formed. In some embodiments, each of the second openings 26b is located at a position below and in spatial communication with a corresponding one of the first openings 26a. In some embodiments, each of the second openings 26b exposes a corresponding one of the stack units 19. As shown in FIGS. 9A and 9D, it is noted that there is no dummy poly gate residues remaining in the second openings 26b after the etching process. In this step, since the width of the second portion 15b of each of the dummy poly gates 15 to be formed with the isolation structure 27 is larger than that of the first portion 15a (i.e., an aspect ratio of the second portion 15b is smaller than that of the first portion 15a), the second portion 15b may be efficiently removed, which is conducive to enhancing a production yield of the semiconductor device 200A. The aspect ratio is defined by a ratio of a depth of the second portion 15b (or the first portion 15a) to the width of the second portion 15b (or the first portion 15a).

In some embodiments, in this step, the second portion 15b of the each of the dummy poly gates 15 to be formed with the isolation structure 27 may not be fully removed in the etching process, so that an end part 15b′ of the second portion 15b remains and is connected to a corresponding adjacent one of the first portions 15a. In some alternative embodiments, the second portion 15b of the each of the dummy poly gates 15 to be formed with the isolation structure 27 may not be fully removed in the etching process, so that two end parts 15b′ of the second portion 15b that are opposite to each other and that are spaced apart from each other by a corresponding one of the second openings 26b in the Y direction remain, and each of the two end parts 15b′ is connected to a corresponding one of the first portions 15a. In this case, the second opening 26b has a length (L2) in the Y direction, and the length (L2) is smaller than a length (L1) of the second portion 15b (see FIGS. 8A and 9A) in the Y direction. In some embodiments, the second portion 15b of the each of the dummy poly gates 15 to be formed with the isolation structure 27 may be fully removed.

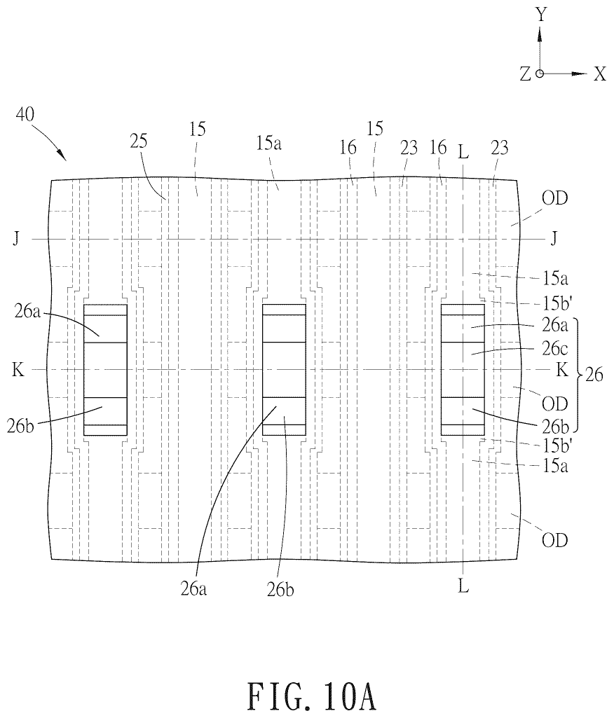

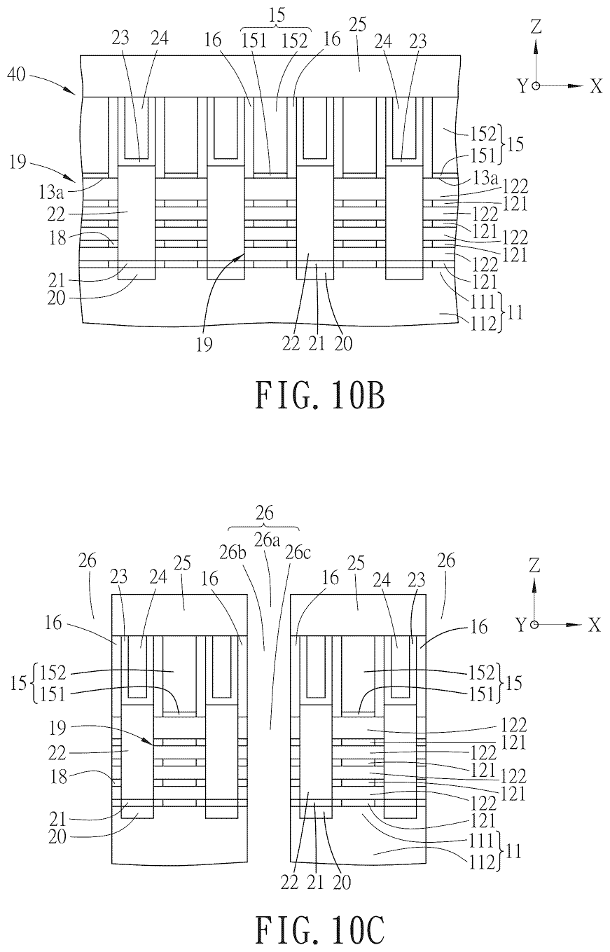

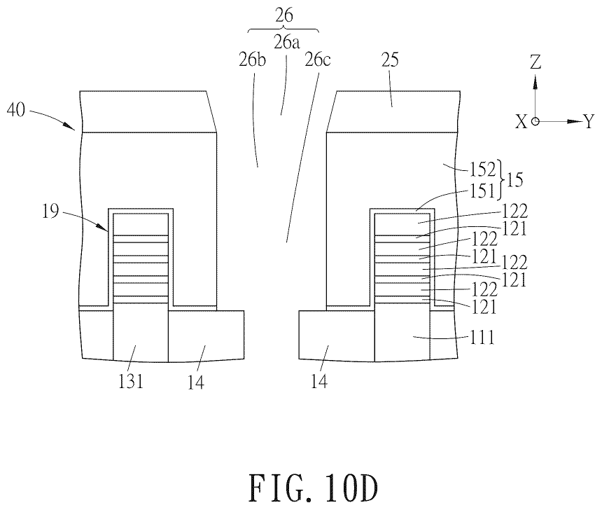

Referring to FIG. 1A and the example illustrated in FIGS. 10A to 10D, the method 100A then proceeds to step S09, where the stack units 19 exposed from the first openings 26a and the second openings 26b (see FIGS. 9C and 9D) are removed. FIG. 10B illustrates a cross-sectional view taken along line J-J of FIG. 10A. FIG. 10C illustrates a cross-sectional view taken along line K-K of FIG. 10A. FIG. 10D illustrates a cross-sectional view taken along line L-L of FIG. 10A. Step S09 may be performed by a suitable etching process, for example, but not limited to, an anisotropic dry etching process or other suitable etching processes. After this step, a plurality of third openings 26c are formed. In some embodiments, each of the third openings 26c is located at a position below and in spatial communication with a corresponding one of the second openings 26b. In some embodiments, each of the first openings 26a, a corresponding one of the second openings 26b, and a corresponding one of the third openings 26c are collectively referred as an opening structure 26 (i.e., a plurality of the opening structures 26 are formed in this step).

Referring to FIG. 1A and the example illustrated in FIGS. 11A to 11D, the method 100A then proceeds to step S10, where an isolation structure 27 is formed by forming a dielectric material layer on the structure shown in FIGS. 10A to 10D to permit the opening structures 26 (see FIGS. 10C and 10D) to be filled with the dielectric material layer, followed by performing a planarization process to remove an excess portion of the dielectric material layer and the patterned mask layer 25. FIG. 11B illustrates a cross-sectional view taken along line M-M of FIG. 11A. FIG. 11C illustrates a cross-sectional view taken along line N-N of FIG. 11A. FIG. 11D illustrates a cross-sectional view taken along line O-O of FIG. 11A. Step S10 may include sub-steps (i) and (ii).

In sub-step (i), the dielectric material layer for forming the isolation structure 27 is formed on the structure shown in FIGS. 10A to 10D to fill the opening structures 26. The dielectric material layer may include, for example, but not limited to, silicon nitride. Other suitable materials for forming the isolation structure 27 are within the contemplated scope of the present disclosure. In some embodiments, the dielectric material layer may be formed by a suitable deposition process, for example, but not limited to, CVD, PVD, ALD, or other suitable deposition processes.

In sub-step (ii), a planarization process (e.g., CMP or other suitable planarization processes) is performed to remove the excess portion of the dielectric material layer and the patterned mask layer 25 (see FIGS. 10B to 10D).

In some embodiments, after removal of the stack units 19 exposed from the first openings 26a and the second openings 26b and before formation of the isolation structure 27, an oxide-based material layer (not shown) may be conformally formed on the structure shown in FIGS. 10A to 10D. In some embodiments, the oxide-based material layer may include, for example, but not limited to, silicon oxide or other suitable oxide-based materials. In some embodiments, the oxide-based material layer may be formed by a suitable deposition process, for example, but not limited to, CVD, PVD, ALD, or other suitable deposition processes.

In some embodiments, the isolation structure 27 is referred to as a CPODE structure, which serves as an isolation structure to isolate two adjacent ones of the OD regions of the semiconductor device 200A. In some embodiments, the semiconductor device 200A may include a plurality of the isolation structures 27. In some embodiments, each of the isolation structures 27 may have a rectangular shape (see FIG. 11A).

FIG. 12A illustrates different configurations of the isolation structures 27 in accordance with some embodiments. In this case, each of the isolation structures 27 may include a main part 271 and two jog parts 272 that respectively protrude from two opposite sides of the main part 271 in the X direction. In some embodiments, each of the two jog parts 272 may be divided into two jog segments 2721, 2722 that respectively protrude from two opposite end regions of the main part 271 in the X direction and that are spaced apart from each other in the Y direction. The isolation structures 27 having the configurations shown in FIG. 12A may be formed from the dummy poly gates 15 (see FIG. 12B), in which each of the jog parts 15b2 of each of second portions 15b of each of the dummy poly gates 15 to be formed with the isolation structures 27 is divided into two jog segments 15b2′ that respectively protrude from two opposite end regions of the main part 15b1 of the each of the second portions 15b of each of the dummy poly gates 15 in the X direction and that are spaced apart from and aligned with each other in the Y direction.

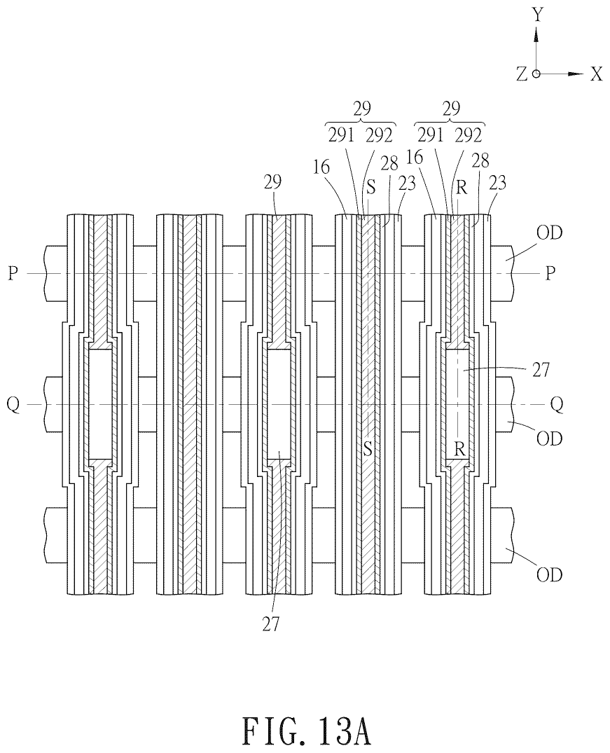

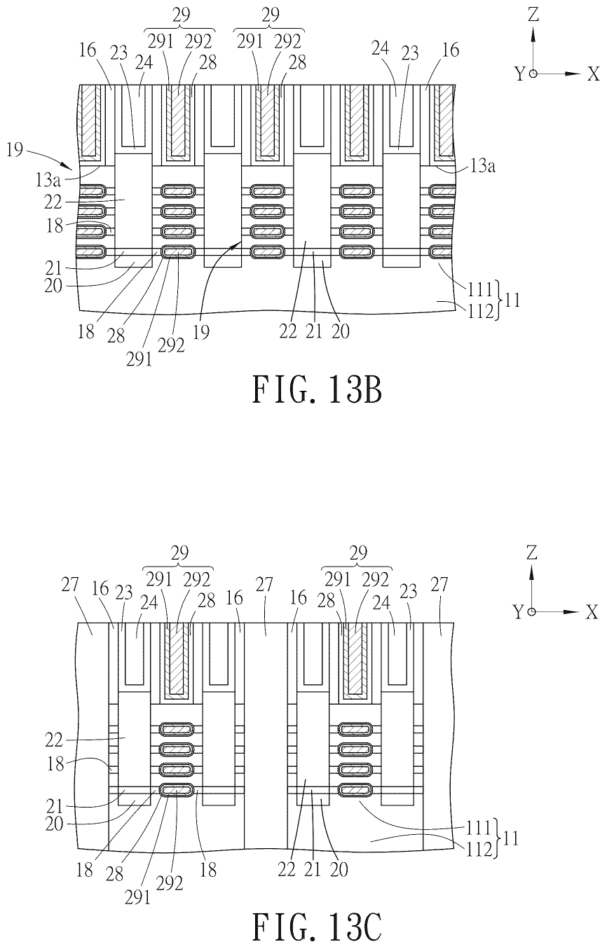

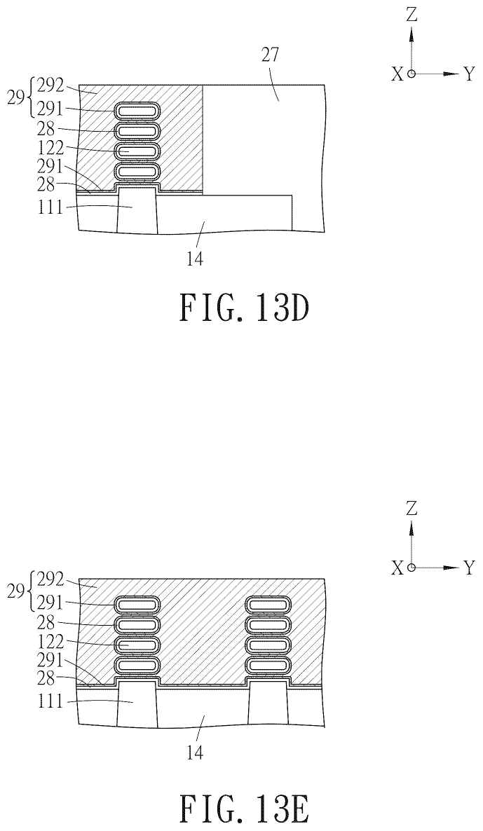

Referring to FIG. 1B and the example illustrated in FIGS. 13A to 13E, the method 100A then proceeds to step S11, where a replacement gate process is performed. FIG. 13B illustrates a cross-sectional view taken along line P-P of FIG. 13A. FIG. 13C illustrates a cross-sectional view taken along line Q-Q of FIG. 13A. FIG. 13D illustrates a cross-sectional view taken along line R-R of FIG. 13A. FIG. 13E illustrates a cross-sectional view taken along line S-S of FIG. 13A. Step S11 may include sub-steps (i) to (iii).

In sub-step (i), the dummy poly gates 15 remaining after step S10 (i.e., the formation of the isolation structures 27) (see FIG. 11A) and the sacrificial features 121 (see FIG. 11D) are removed using one or more suitable etching processes to form a plurality of cavities (not shown).

In sub-step (ii), materials for forming a plurality of high-k material features 28 and a plurality of metal gate features 29 are sequentially formed on the previously obtained structure and in the cavities using one or more suitable deposition processes (e.g., CVD, ALD, etc.), followed by performing a planarization process (e.g., CMP or other suitable planarization processes) to remove an excess portion of each of the abovementioned materials, thereby obtaining the high-k material features 28 and the metal gate features 29.

The high-k material features 28 are respectively disposed around the metal gate features 29. In some embodiments, the high-k material features 28 may include, for example, but not limited to, hafnium oxide, zirconium oxide, zirconium aluminum oxide, hafnium aluminum oxide, hafnium silicon oxide, aluminum oxide, or combinations thereof. Other suitable materials for the high-k material features 28 are within the contemplated scope of the present disclosure.

Each of the metal gate features 29 may be configured as a multi-layered structure that includes at least one work function metal layer 291, and an electrically conductive material layer 292.

The at least one work function metal layer 291 of each of the metal gate features 29 is surrounded by a corresponding one of the high-k material features 28 (see FIGS. 13B and 13C). In some embodiments, the at least one work function metal layer 291 may include, for example, but not limited to, titanium nitride, tantalum nitride, ruthenium, molybdenum, tungsten, tungsten nitride, platinum, zirconium disilicide, molybdenum disilicide, tantalum disilicide, nickel disilicide, titanium, aluminum, silver, manganese, zirconium, tantalum carbide, tantalum carbide nitride, tantalum silicon nitride, titanium silicon nitride, or combinations thereof. Other suitable materials for the at least one work function metal layer 291 are within the contemplated scope of the present disclosure. In some embodiments, the at least one work function metal layer 291 may be formed by a suitable deposition process, for example, but not limited to, CVD, PVD, ALD, or other suitable deposition processes.

The electrically conductive material layer 292 is surrounded by the at least one work function metal layer 291. The electrically conductive material layer 292 may include, for example, but not limited to, aluminum, tungsten, cobalt, or combinations thereof. Other suitable materials for the electrically conductive material layer 292 are within the contemplated scope of the present disclosure. The electrically conductive material layer 292 may be formed by a suitable deposition process, for example, CVD, PVD, electroless plating, or other suitable deposition processes.

In sub-step (iii), a planarization process (e.g., CMP or other suitable planarization processes) is performed to remove an excess portion of each of the materials for forming the high-k material features 28 and the metal gate features 29, so as to obtain the high-k material features 28 and the metal gate features 29.

It is noted that in step S11, an excess portion of each of the metal gate features 29 may extend into a corresponding one of the isolation structures 27 at an interface between the each of the metal gate features 29 and the corresponding one of the isolation structures 27, and may be in contact with other elements (e.g., contact plugs (i.e., metal on diffusion (MD)), resulting in an electrical leakage.

In some embodiments, before formation of the high-k material features 28, a plurality of interfacial features (not shown) are respectively formed to cover the channel features 122. In some embodiments, the interfacial features may include, for example, but not limited to, silicon oxide, silicon nitride, silicon oxynitride, or combinations thereof. Other suitable materials for the interfacial features are within the contemplated scope of the present disclosure.

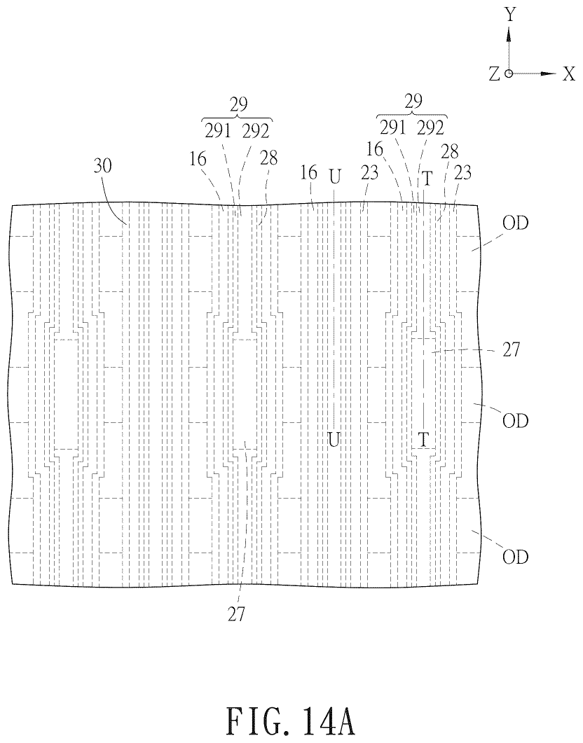

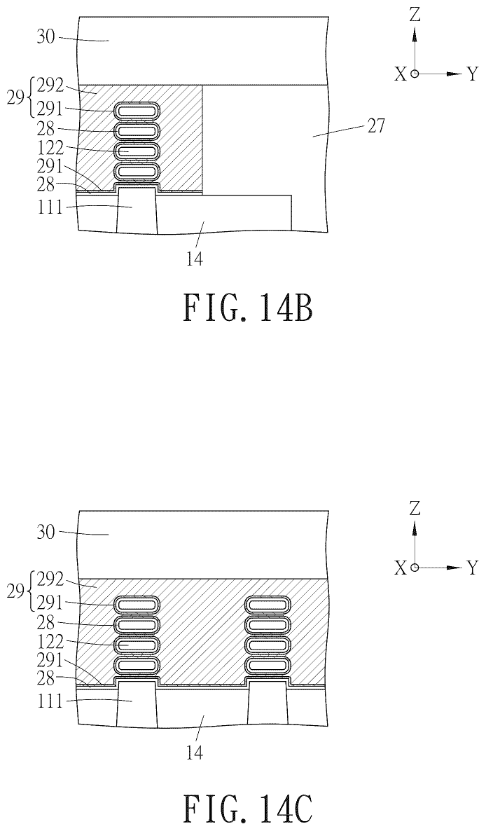

Referring to FIG. 1B and the example illustrated in FIGS. 14A to 14C, the method 100A then proceeds to step S12, where a hard mask layer 30 is formed over the previously obtained structure shown in FIGS. 13A to 13E. FIG. 14B illustrates a cross-sectional view taken along line T-T of FIG. 14A. FIG. 14C illustrates a cross-sectional view taken along line U-U of FIG. 14A. In some embodiments, the hard mask layer 30 may include, for example, but not limited to, silicon nitride. Other suitable materials for the hard mask layer 30 are within the contemplated scope of the present disclosure. In some embodiments, the hard mask layer 30 may be formed by a suitable deposition process, for example, but not limited to, CVD, PVD, or other suitable deposition processes.

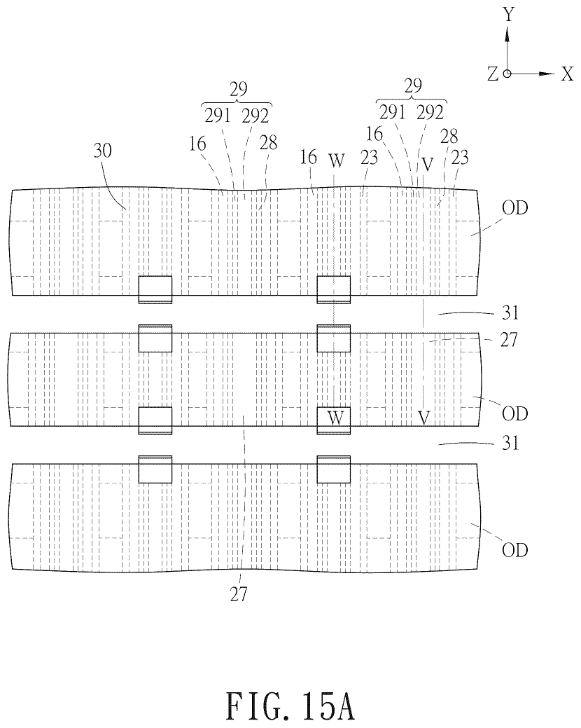

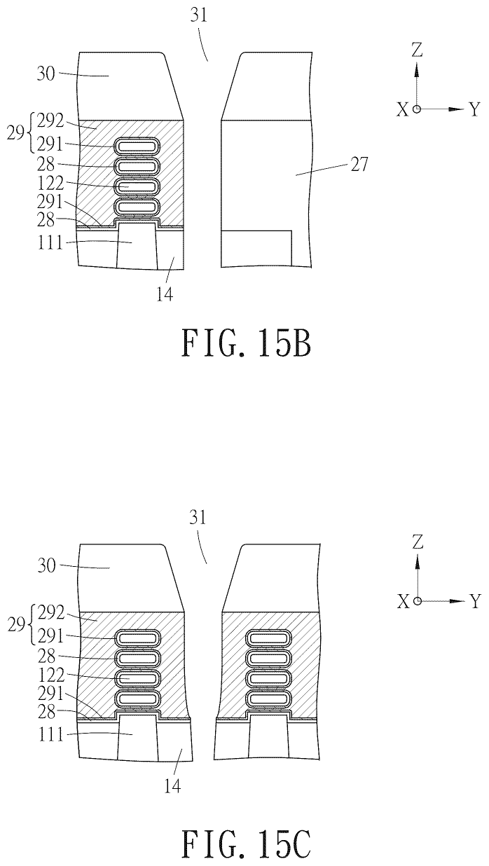

Referring to FIG. 1B and the example illustrated in FIGS. 15A to 15C, the method 100A then proceeds to step S13, where a patterning process is performed to pattern the previously obtained structure shown in FIGS. 14A to 14C, so as to form a plurality of trenches 31, each of which may be referred to as a cut metal gate (CMG) trench. FIG. 15B illustrates a cross-sectional view taken along line V-V of FIG. 15A. FIG. 15C illustrates a cross-sectional view taken along line W-W of FIG. 15A. Step S13 may be performed by a photolithography process, which is described in step S02. In some embodiments, as shown in FIG. 15B, the trench 31 may penetrate the hard mask layer 30, the metal gate features 29, the isolation structures 27, and corresponding ones of the isolation portions 14. In some embodiments, as shown in FIG. 15C, the trench 31 may penetrate the hard mask layer 30, the metal gate features 29, one of the high-k material features 28, and corresponding ones of the isolation portions 14. After this step, the excess portion of each of the metal gate features 29 at the interface between the each of the metal gate features 29 and the corresponding one of the isolation structures 27 may be fully removed, which is conducive for preventing electrical leakage in the semiconductor device 200A.

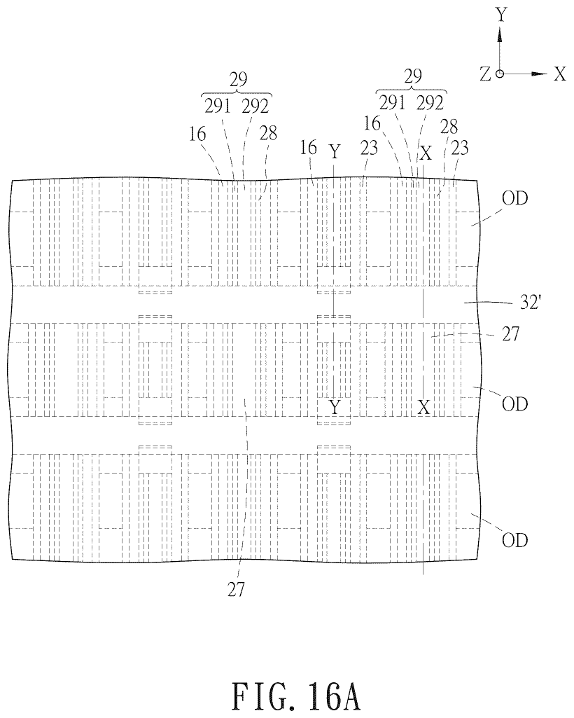

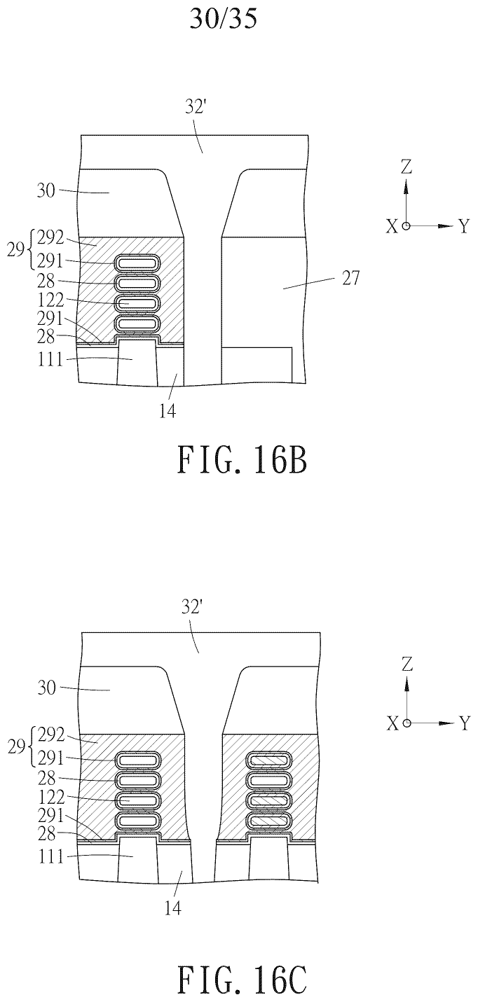

Referring to FIG. 1B and the example illustrated in FIGS. 16A to 16C, the method 100A then proceeds to step S14, where an oxide layer 32′ is formed on the previously obtained structure shown in FIGS. 15A to 15C and fills the trenches 31. FIG. 16B illustrates a cross-sectional view taken along line X-X of FIG. 16A. FIG. 16C illustrates a cross-sectional view taken along line Y-Y of FIG. 16A. In some embodiments, the oxide layer 32′ may include, for example, but not limited to, plasma-enhanced oxide. Other suitable oxide-based materials for the oxide layer 32′ are within the contemplated scope of the present disclosure. In some embodiments, the oxide layer 32′ may be formed by a suitable deposition process, for example, but not limited to, CVD, PVD, ALD, or other suitable deposition processes.

Referring to FIG. 1B and the example illustrated in FIGS. 17A to 17C, the method 100A then proceeds to step S15, where an excess portion of the oxide layer 32′ and the hard mask layer 30 are removed. FIG. 17B illustrates a cross-sectional view taken along line Z-Z of FIG. 17A. FIG. 17C illustrates a cross-sectional view taken along line A′-A′ of FIG. 17A. Step S15 may be performed by a suitable planarization process (e.g., CMP or other suitable planarization processes). After this step, the oxide layer 32′ is formed into a plurality of isolation structures 32, each of which extends in the X direction. In some embodiments, each of the metal gate features 29 is separated from a corresponding one of the isolation structures 27 by a corresponding one of the isolation structures 32. After step S15, the semiconductor device 200A is obtained.

FIGS. 18A and 18B illustrate a schematic view of a semiconductor device 200B in accordance with some embodiments. FIG. 18B illustrates a cross-sectional view taken along line B′-B′ of FIG. 17A. The structure of the semiconductor device 200B is similar to that of the semiconductor device 200A, except that, in the semiconductor device 200B, each of the isolation structures 32 includes a main portion 321 and a plurality of first jog portions 322 that protrude from a first side of the main portion 321 in the Y direction, and that are separated from one another in the X direction.

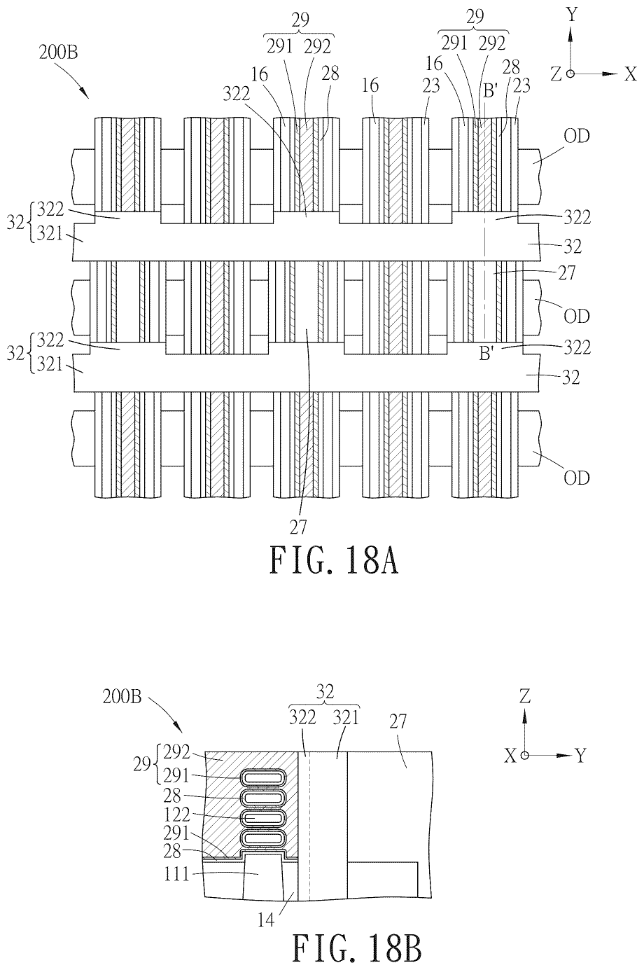

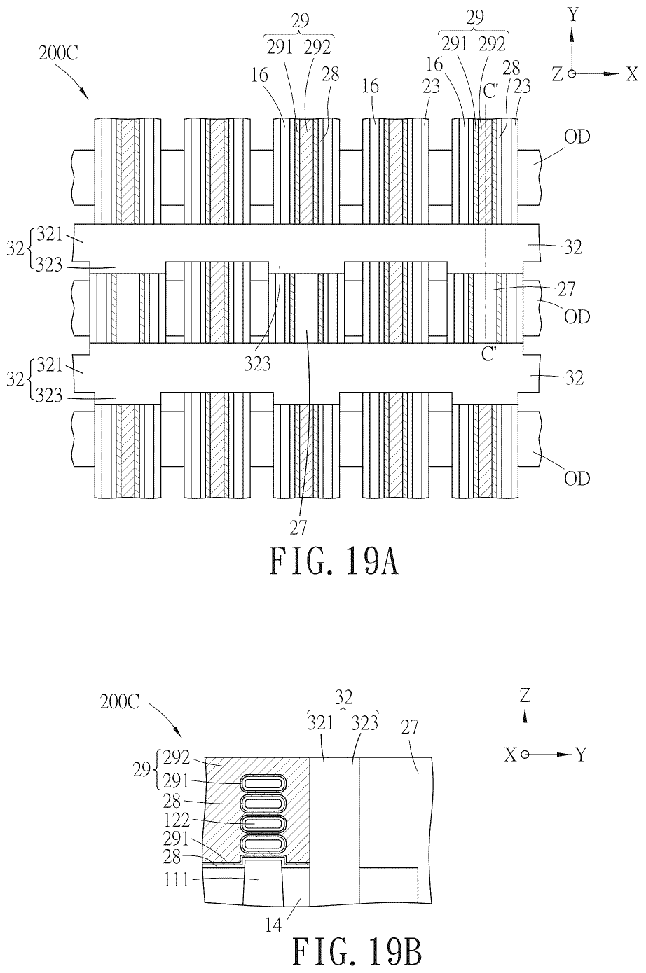

FIGS. 19A and 19B illustrate a schematic view of a semiconductor device 200C in accordance with some embodiments. FIG. 19B illustrates a cross-sectional view taken along line C′-C′ of FIG. 19A. The structure of the semiconductor device 200C is similar to that of the semiconductor device 200A, except that, in the semiconductor device 200C, each of the isolation structures 32 includes the main portion 321 and a plurality of second jog portions 323 that protrude from a second side of the main portion 321 in the Y direction, and that are separated from one another in the X direction. The second side of the main portion 321 is opposite to the first side of the main portion 321 in the Y direction.

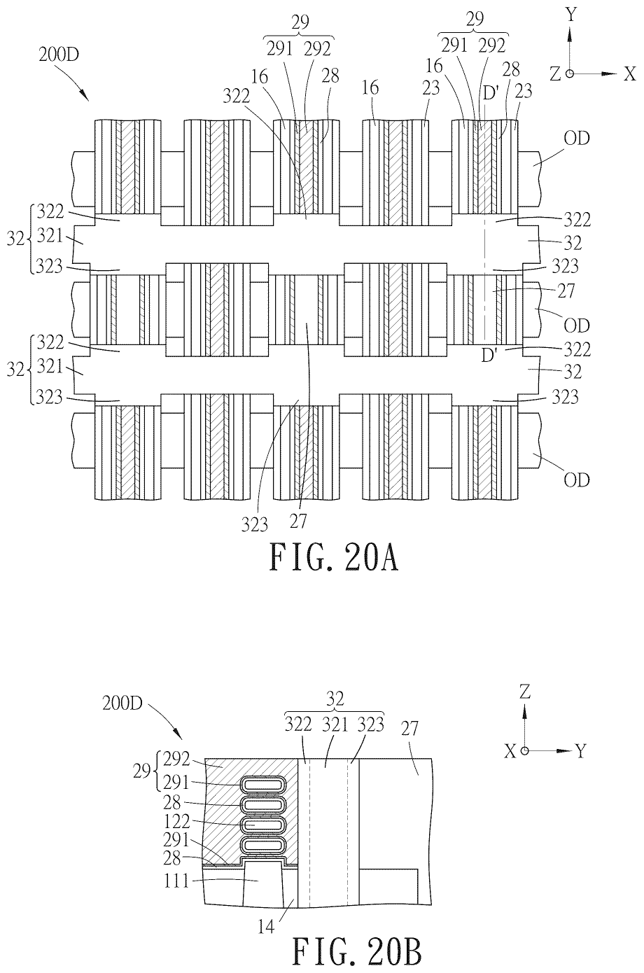

FIGS. 20A and 20B illustrate a schematic view of a semiconductor device 200D in accordance with some embodiments. FIG. 20B illustrates a cross-sectional view taken along line D′-D′ of FIG. 20A. The structure of the semiconductor device 200D is similar to that of the semiconductor device 200A, except that, in the semiconductor device 200D, each of the isolation structures 32 includes the main portion 321 and the first jog portions 322 and the second jog portions 323 that oppositely protrude from the main portion 321 in the Y direction.

In a process for manufacturing a semiconductor device of this disclosure, by increasing a width of a portion of a dummy poly gate to be etched in a subsequent etching process for forming a trench in the formation of a connected polysilicon on oxide-definition (OD) edge (CPODE)) structure, the portion of the dummy poly gate may be fully removed, and no polysilicon residues remain at an interface between the CPODE structure and a remainder of the dummy poly gate after the etching process. Therefore, a production yield of the semiconductor device of this disclosure may be increased.

In accordance with some embodiments of the present disclosure, a method for manufacturing a semiconductor device includes: forming a dummy poly gate on a common edge of a first oxide-definition region and a second oxide-definition region, the dummy poly gate covering a stack unit, and including two first portions and a second portion disposed between the two first portions in a first direction, each of the two first portions having a width in a second direction transverse to the first direction, the second portion having a width in the second direction, the width of the second portion being larger than the width of each of the two first portions; forming a first source/drain feature and a second source/drain feature on the first oxide-definition region and the second oxide-definition region, respectively; removing the second portion of the dummy poly gate to form a first opening that exposes the stack unit; removing the stack unit to form a second opening that is in spatial communication with the first opening; and forming an isolation structure in the first opening and the second opening.

In accordance with some embodiments of the present disclosure, the second portion of the dummy poly gate includes a main part and two jog parts that respectively protrude from two opposite sides of the main part in the second direction.

In accordance with some embodiments of the present disclosure, a width of the main part of the second portion in the second direction is the same as the width of the first portion in the second direction.

In accordance with some embodiments of the present disclosure, each of the two jog parts includes two jog segments that respectively protrude from two opposite end regions of the main part in the second direction, and that are spaced apart from each other in the first direction.

In accordance with some embodiments of the present disclosure, after formation of the first opening, an end region of the second portion remains and is connected to a corresponding one of the two first portions.

In accordance with some embodiments of the present disclosure, the first opening has a length in the first direction that is smaller than a length of the second portion in the first direction.

In accordance with some embodiments of the present disclosure, after formation of the first opening, two end regions of the second portion that are opposite to each other in the first direction remain, and are respectively connected to the two first portions.

In accordance with some embodiments of the present disclosure, the first opening has a length in the first direction that is smaller than a length of the second portion in the first direction.

In accordance with some embodiments of the present disclosure, a method for manufacturing a semiconductor device includes: forming a dummy poly gate on a common edge of a first oxide-definition region and a second oxide-definition region, the dummy poly gate covering a stack unit, and including a first portion and a second portion connected to the first portion in a first direction, the first portion having a width in a second direction transverse to the first direction, the second portion having a width in the second direction, the width of the second portion being larger than the width of the first portion; forming a first source/drain feature and a second source/drain feature on the first oxide-definition region and the second oxide-definition region, respectively; removing the second portion of the dummy poly gate to form a first opening that exposes the stack unit; removing the stack unit to form a second opening that is in spatial communication with the first opening; forming a first isolation structure in the first opening and the second opening; removing a remainder of the dummy poly gate after the formation of the first isolation structure to form a cavity; and forming a metal gate feature to fill the cavity.

In accordance with some embodiments of the present disclosure, the first isolation structure includes a main part and two jog parts that respectively protrude from two opposite sides of the main part in the second direction.

In accordance with some embodiments of the present disclosure, each of the two jog parts includes two jog segments that respectively protrude from two opposite end regions of the main part in the second direction and that are spaced apart from each other in the first direction.

In accordance with some embodiments of the present disclosure, the method for manufacturing the semiconductor device further includes: after formation of the metal gate feature, forming a trench that extend in the second direction and that penetrates a portion of the first isolation structure and a portion of the metal gate feature; and forming a second isolation structure in the trench.

In accordance with some embodiments of the present disclosure, the second isolation structure includes a main portion and a first jog portion that protrudes from the main portion in the first direction.

In accordance with some embodiments of the present disclosure, the second isolation structure further includes a second jog portion that protrudes from the main portion opposite to the first jog portion in the first direction.

In accordance with some embodiments of the present disclosure, the first isolation structure and the second isolation structure are made of different materials.

In accordance with some embodiments of the present disclosure, a semiconductor device includes a semiconductor structure, a first isolation structure, and a metal gate feature. The semiconductor structure includes a first oxide-definition region and a second oxide-definition region that are aligned with each other in the first direction. The first isolation structure is disposed in the semiconductor structure and at a common edge of the first oxide-definition region and the second oxide-definition region, and has a width in the first direction. The metal gate feature is disposed in the semiconductor structure, and is spaced apart from the first isolation structure in the second direction transverse to the first direction. The metal gate feature has a width in the first direction. The width of the first isolation structure is larger than the width of the metal gate feature.

In accordance with some embodiments of the present disclosure, the first isolation structure includes a main part and two jog parts that respectively protrude from two opposite sides of the main part in the first direction.

In accordance with some embodiments of the present disclosure, each of the two jog parts includes two jog segments that respectively protrude from two opposite end regions of the main part in the first direction, and that are spaced apart from each other in the second direction.

In accordance with some embodiments of the present disclosure, the semiconductor device further includes a second isolation structure that extends in the first direction and that separates the metal gate feature and the first isolation structure.

In accordance with some embodiments of the present disclosure, the second isolation structure includes a main portion and a jog portion that protrudes from the main portion in the second direction, and that separates the metal gate feature and the main portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a dummy poly gate on a common edge of a first oxide-definition region and a second oxide-definition region, the dummy poly gate covering a stack unit, and including two first portions and a second portion disposed between the two first portions in a first direction, each of the two first portions having a width in a second direction transverse to the first direction, the second portion having a width in the second direction, the width of the second portion being larger than the width of each of the two first portions;
forming a first source/drain feature and a second source/drain feature on the first oxide-definition region and the second oxide-definition region, respectively;
removing the second portion of the dummy poly gate to form a first opening that exposes the stack unit;
removing the stack unit to form a second opening that is in spatial communication with the first opening; and
forming an isolation structure in the first opening and the second opening.

2. The method as claimed in claim 1, wherein the second portion of the dummy poly gate includes a main part and two jog parts that respectively protrude from two opposite sides of the main part in the second direction.

3. The method as claimed in claim 2, wherein a width of the main part of the second portion in the second direction is the same as the width of the first portion in the second direction.

4. The method as claimed in claim 2, wherein each of the two jog parts includes two jog segments that respectively protrude from two opposite end regions of the main part in the second direction, and that are spaced apart from each other in the first direction.

5. The method as claimed in claim 1, wherein after formation of the first opening, an end region of the second portion remains and is connected to a corresponding one of the two first portions.

6. The method as claimed in claim 5, wherein the first opening has a length in the first direction that is smaller than a length of the second portion in the first direction.

7. The method as claimed in claim 1, wherein after formation of the first opening, two end regions of the second portion that are opposite to each other in the first direction remain, and are respectively connected to the two first portions.

8. The method as claimed in claim 7, wherein the first opening has a length in the first direction that is smaller than a length of the second portion in the first direction.

9. A method for manufacturing a semiconductor device, comprising:
forming a dummy poly gate on a common edge of a first oxide-definition region and a second oxide-definition region, the dummy poly gate covering a stack unit, and including a first portion and a second portion connected to the first portion in a first direction, the first portion having a width in a second direction transverse to the first direction, the second portion having a width in the second direction, the width of the second portion being larger than the width of the first portion;
forming a first source/drain feature and a second source/drain feature on the first oxide-definition region and the second oxide-definition region, respectively;
removing the second portion of the dummy poly gate to form a first opening that exposes the stack unit;
removing the stack unit to form a second opening that is in spatial communication with the first opening;
forming a first isolation structure in the first opening and the second opening;
removing a remainder of the dummy poly gate after the formation of the first isolation structure to form a cavity; and
forming a metal gate feature to fill the cavity.

10. The method as claimed in claim 9, wherein the first isolation structure includes a main part and two jog parts that respectively protrude from two opposite sides of the main part in the second direction.

11. The method as claimed in claim 10, wherein each of the two jog parts includes two jog segments that respectively protrude from two opposite end regions of the main part in the second direction and that are spaced apart from each other in the first direction.

12. The method as claimed in claim 9, further comprising, after formation of the metal gate feature,
forming a trench that extend in the second direction and that penetrates a portion of the first isolation structure and a portion of the metal gate feature; and
forming a second isolation structure in the trench.

13. The method as claimed in claim 12, wherein the second isolation structure includes a main portion and a first jog portion that protrudes from the main portion in the first direction.

14. The method as claimed in claim 13, wherein the second isolation structure further includes a second jog portion that protrudes from the main portion opposite to the first jog portion in the first direction.

15. The method as claimed in claim 12, wherein the first isolation structure and the second isolation structure are made of different materials.

16. A semiconductor device, comprising:
a semiconductor structure including a first oxide-definition region and a second oxide-definition region that are aligned with each other in the first direction;
a first isolation structure disposed in the semiconductor structure and at a common edge of the first oxide-definition region and the second oxide-definition region, and having a width in the first direction; and
a metal gate feature that is disposed in the semiconductor structure, and that is spaced apart from the first isolation structure in a second direction transverse to the first direction, the metal gate feature having a width in the first direction,
the width of the first isolation structure being larger than the width of the metal gate feature.

17. The semiconductor device as claimed in claim 16, wherein the first isolation structure includes a main part and two jog parts that respectively protrude from two opposite sides of the main part in the first direction.

18. The semiconductor device as claimed in claim 17, wherein each of the two jog parts includes two jog segments that respectively protrude from two opposite end regions of the main part in the first direction, and that are spaced apart from each other in the second direction.

19. The semiconductor device as claimed in claim 16, further comprising a second isolation structure that extends in the first direction and that separates the metal gate feature and the first isolation structure.

20. The semiconductor device as claimed in claim 19, wherein the second isolation structure includes a main portion and a jog portion that protrudes from the main portion in the second direction, and that separates the metal gate feature and the main portion.
